(19) United States
(12) Patent Application Publication
(10) Pub. No.: US 2022/0260529 A1
(43) Pub. Date: Aug. 18, 2022

(54) ROBOTIC MAGNETIC FLUX INSPECTION SYSTEM FOR BROADCAST TOWER SUPPORT CABLES

(71) Applicant: INFRASTRUCTURE PRESERVATION CORPORATION, Largo, FL (US)

(72) Inventor: William SEAVEY, Largo, FL (US)

(21) Appl. No.: 17/691,560

(22) Filed: Mar. 10, 2022

Related U.S. Application Data
(63) Continuation-in-part of application No. 16/360,765, filed on Mar. 21, 2019, now Pat. No. 11,112,382.
(60) Provisional application No. 63/159,754, filed on Mar. 11, 2021.

(51) Int. Cl. G01N 27/904; G01R 33/02

(52) U.S. Cl. CPC G01N 27/904; G01R 33/0213

(57) ABSTRACT

A robotic inspection system for broadcast tower support cables includes a self-propelled sensing device configured to move along a broadcast tower support cable for taking main magnetic flux (MMF) readings as the sensing device moves along the support cable. The system also includes a control station configured to wirelessly interface with the sensing device and to generate a broadcast tower support cable condition assessment report from the MMF readings to identify locations and sizes of deterioration of the broadcast tower support cable. The sensing devices includes a sensing array that is insulated from the electromagnetic radiation emitted from the broadcast tower.

### RELATED APPLICATION

The present invention is related to U.S. Provisional Patent Application Ser. No. 63/159,754 filed Mar. 11, 2021, and a continuation-in-part of U.S. patent application Ser. No. 16/360,765 filed Mar. 21, 2019, now U.S. Pat. No. 11,112,382 issued Sep. 7, 2021, the entire contents of which are incorporated herein by reference.

### TECHNICAL FIELD

The present invention relates to the field of cable inspection devices, and, more particularly, to a robotic magnetic flux inspection system for broadcast tower support cables and related methods.

### BACKGROUND

The corrosion of broadcast tower support cables is a serious problem that can compromise the structural integrity of a broadcast tower with minimal visual signs. Consequently, the early detection of deficiencies of the cables is a major safety issue. Without detection, steel corrosion can occur to the point of failure without any major outward visual signs.

Methods of locating deficiencies of the broadcast tower support cables is time consuming and labor intensive. Accordingly, there is a need to improve the inspection of the cables that is more efficient and provides early detection of potential problems. It is, therefore, to the effective resolution of the aforementioned problems and shortcomings of the prior art that the present invention is directed.

However, in view of the prior art at the time the present invention was made, it was not obvious to those of ordinary skill in the pertinent art how the identified needs could be fulfilled.

### SUMMARY

In a particular embodiment, a robotic magnetic flux inspection system for broadcast tower support cables is disclosed. The system includes a self-propelled sensing device configured to move along a broadcast tower support cable to detect magnetic flux leakage. In addition, the system includes a control station configured to wirelessly interface with the sensing device, where the control station is configured to generate a broadcast tower support cable condition assessment report from the detection of the magnetic flux leakage to identify locations and sizes of the discontinuities within the support cables.

The sensing device may have an insulated sensor array and a plurality of sets of rare-earth magnets grouped in measurement channels, where each of which delivers a cross-sectional magnetic field. The sensing device may include a processor configured to analyze raw voltage measurements, and have an annulus shape.

The sensor array may have an inductive coil sensor configured to detect the magnetic flux leakage to indicate a discontinuity within the broadcast tower support cables, or a Hall effect sensor configured to detect the magnetic flux leakage to indicate a discontinuity within the support cables.

The magnets are configured to magnetize the support cable along a longitudinal direction, and the sensor array is configured to detect the magnetic flux leakage perpendicular to a surface of the broadcast tower support cables.

In addition, the system may include a control station configured to wirelessly interface with the sensing device and to generate a broadcast tower support cable condition assessment report from the sensing device to identify locations of potential problem areas of the support cables.

An advantage of the self-propelled sensing device is that it can operate in windy and adverse weather conditions. The system also does not require lane closure to operate because there is no need for lifts, and poses virtually no risk to public safety or to the inspector.

### BRIEF DESCRIPTION OF THE DRAWINGS

FIG. 1 is a perspective view of a self-propelled sensing device in an open position in accordance with an embodiment of the present invention;

FIG. 2 is an elevational view of the sensing device secured around a broadcast tower support cable;

FIG. 3 is a front view of an interior of the sensing device secured to the support cable;

FIG. 4 is an elevational view of the sensing device secured to the broadcast tower support cable with the drive wheels in a disengaged position;

FIG. 5 is a top view of the sensing device secured to the support cable with the wheels in an engaged position;

FIG. 6 is a perspective view of a portion of an inductive coil in accordance with an embodiment of the present invention;

FIG. 7 is a schematic of a control station and joystick configured to wirelessly communicate with the sensing device; and

FIG. 8 is an exemplary graph generated using data from the sensing device.

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

A robotic magnetic flux inspection system for broadcast tower support cables (also referred to as “guy wires”) disclosed herein is a comprehensive inspection system that utilizes a Magnetic Flux Leakage (MFL) nondestructive evaluation (NDE) system which is nondestructive testing (NDT) technology in order to locate and assess deterioration in the support cables.

In particular, cross-sectional damage can occur in broadcast tower support cables due to corrosion and fracture, which can lead to stress concentrations. Cross-sectional damage can be a direct cause of structural failure. Therefore, nondestructive evaluation (NDE) is necessary to detect the initial stages of cross sectional damage in a cable. However, it is difficult to monitor the condition of most cables, as the damage can be invisible and inaccessibly located. Accordingly, the present invention utilizes a magnetic flux leakage (MFL) system to detect discontinuities.

The MFL system includes magnetizing the support cables of the broadcast towers. The cables that are magnetized have a magnetic field in and around them. The magnetic field spreads out when it encounters a small air gap created by a discontinuity and it appears to leak out of the cables. A strong permanent magnet or an electromagnet is used to establish a magnetic flux in the broadcast tower support cables to be inspected. When there is no defect, the flux in the metal remains uniform. However, when there is a discontinuity the flux leaks out of the metal near the discontinuity. A sensor array is configured to detect this flux leakage and to generate an electric signal that is proportional to the magnetic flux leakage.

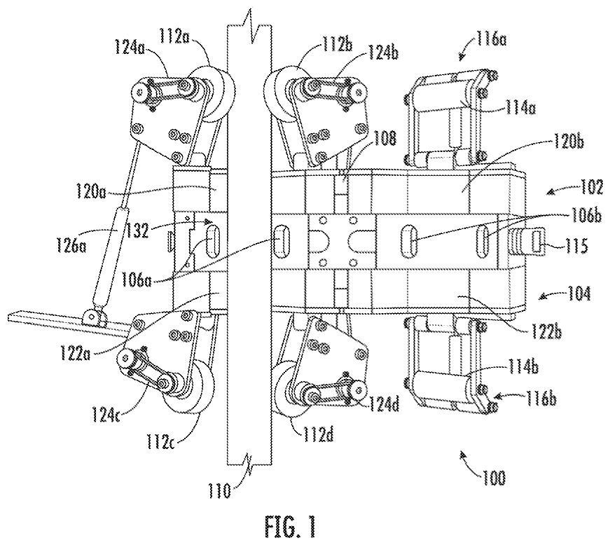

Referring now to FIGS. 1-5, the system includes a self-propelled sensing device 100, which may be wireless and battery operated. In a particular embodiment, the self-propelled sensing device 100 is configured to move up and down support cables 110 performing an MRI like inspection. The inspections are real-time with minimum back office processing.

In a particular illustrative embodiment, the sensing device 100 implements Magnetic Flux Leakage (MFL) methodology described above to generate the data. MFL allows an inspector to efficiently perform the MRI like inspection of the broadcast tower support cables 110.

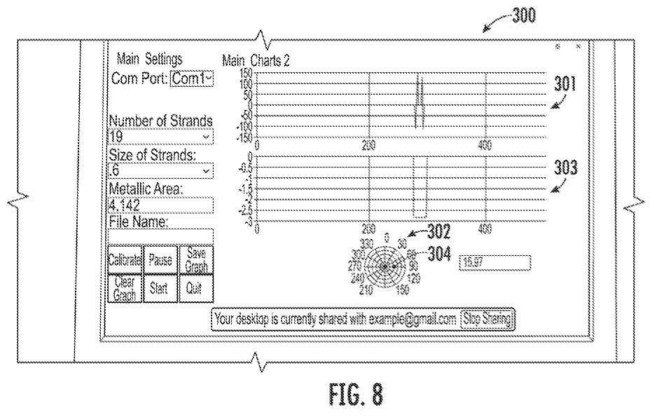

In a particular illustrative embodiment, the sensing device 100 uses the magnetic flux leakage (MFL) method described above to generate a visual indicator of the condition of the support cables 110. For example, the visual indicator may be a two dimensional graph (as shown in FIG. 8 discussed below) that indicates where the discontinuity within the support cable 110 is located and to what degree. The sensing device 100 takes multiple measurements of the magnetic field of the support cable 110 and combines these measurements to provide information of the magnetic properties of the process volume to indicate the extent of loss of magnetic area. This correlates to the amount and location of steel within the support cable 110 that may be damaged.

The sensing device 100 includes a first magnet 102 having a first polarity and a second magnet 104 having a second polarity. The first and second magnets 102, 104 may comprise sets of rare-earth magnets grouped in measurement channels, where each of which delivers a cross-sectional magnetic field. The sensing device 100 also includes an inductive coil 134 and a sensor array 106a, 106b that may be coupled to a processor (e.g. of a control station 304 discussed below) that is configured to analyze raw voltage measurements from the sensor array 106a, 106b using algorithms and provide analysis and export of graphical data. The sensor array 106a, 106b is configured to detect the magnetic flux leakage perpendicular to a surface of the support cables 110. The sensor array 106a, 106b comprises an inductive coil sensor or Hall effect sensor configured to detect the magnetic flux leakage to indicate a discontinuity within the support cables 110.

As shown in FIG. 1, the first magnet 102 comprises two halves 120a, 120b, that are hingedly coupled to each other by a hinge 108 and secured together using clasp 115. Similarly, the second magnet 104 comprises two halves 122a, 122b that are hingedly coupled to each other. Accordingly, the first and second magnets 102, 104 can be swung apart so that the sensing device 100 can be secured completely around the broadcast tower support cable 110.

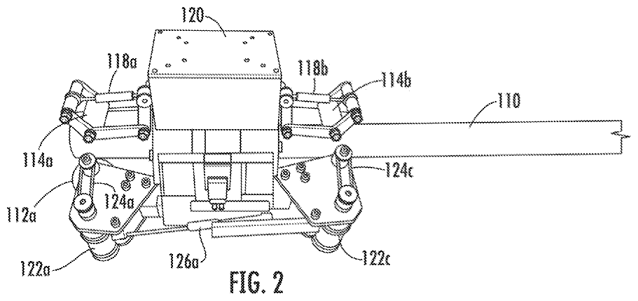

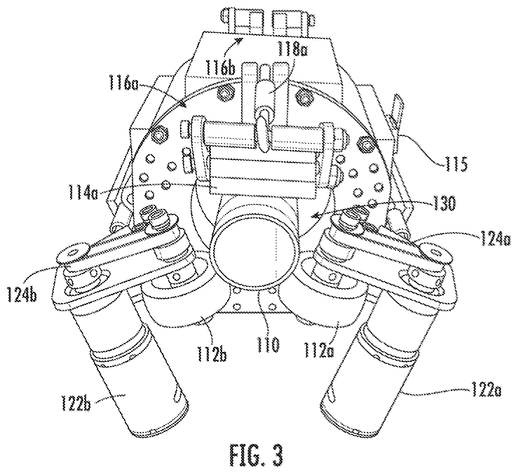

Once the sensing device 100 is secured to the support cable 110 creating a center aperture 130 as shown in FIGS. 2 and 3, rollers 114a, 114b can be adjusted using respective roller clamps 116a, 116b so that the first and second magnets 102, 104 can be rolled along the support cable 110 passing adjacent within a few inches of the exterior surface of the support cable 110.

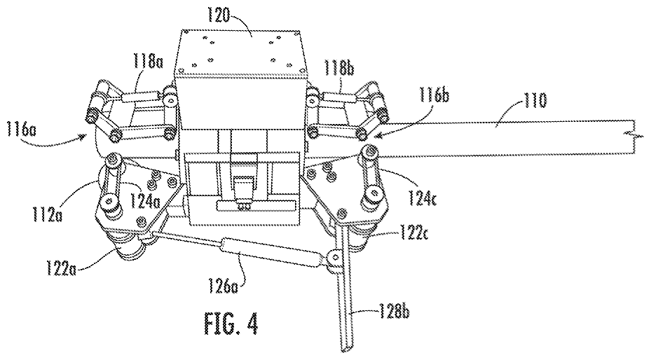

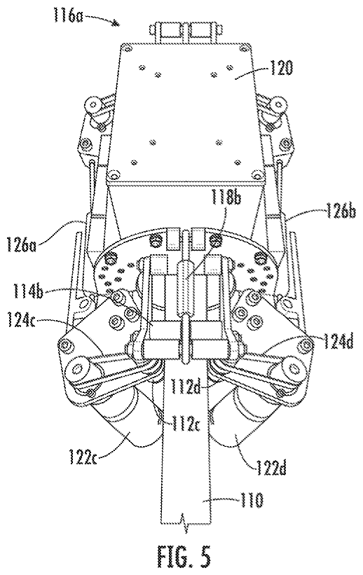

The self-propelled sensing device 100 is latched around the support cable 110 of a broadcast tower and wheels 112a-d are then moved from a disengaged position as shown in FIG. 4, to where the wheels 112a-d are engaged with the support cable 110 as shown in FIG. 5.

FIG. 5 is a top view of the self-propelled sensing device 100 where an insulated housing 120 for the electronic controls is mounted to prevent interference from electromagnetic radiation emitting from the broadcast tower. This include shielding from frequencies from 80 mgz to 960. For example, copper may be used around the inductive coil and as a lining within the insulated housing 120. The sensing device 100 is configured to travel up to 3000 ft. The housing 120 also comprises a three section antenna array configured to support directional communications for movement of the sensing device 100, data transfer of MFL data, and a video navigation downlink.

Adjustment bolts or a turnbuckle 118a, 118b may be used to secure the attachment of the sensing device 100 to the support cables 110 by the rollers 114a, 114b. The sensing device 100 is then powered up. The sensing device 100 is configured to perform a short diagnostic to insure that the communications are working and that the mechanical robotics are functional and remote controllable and to make sure the sensing device 100 is operable and transmitting the main magnetic flux (MMF) data to the control station 304.

The sensing device 100 is checked for maneuverability up and down the support cables 110. Once all functionalities are confirmed, then the recording is checked for performance and quality. In addition, the power system is checked for appropriate amps and voltage. The sensing device 100 is then ready to be deployed up the support cable 110 towards its upper end. The rollers 114a, 114b of the sensing device 100 have sufficient gripping power to maintain a solid and consistent connection with the support cable 110 as the wheels 112a-d drive it up and down the broadcast tower support cable 110.

The inspector 300 stands at the control station 304 that may include a joystick 306 to control movement of the sensing device 100. The sensing device 100 uses wireless connectivity to transmit the MRI like data to the control station 304 where the inspector 300 performs real-time assessments of the support cables 110.

In particular, the sensing device 100 is a comprehensive maneuverable inspection device that can travel up and down the broadcast tower support cables 110. The sensing device 100 includes wireless communications equipment in order to receive command and control commands and also to wirelessly transmit main magnetic flux (MMF) data.

The self-propelled sensing device 100 is configured to mount to selected broadcast tower support cables 110 and travel the length of a cable 110 while being fully controlled and monitored remotely. As explained above, the sensing device 100 is configured to be secured around the support cable 110 using the roller clamps 116a, 116b that allow them to swing open and closed in order to be secured around the support cable 110.

The wheels 112a-d for the sensing device 100 may comprise rubber adapted for griping the support cable 110 and for mobility. The sensing device 100 is able to transverse the support cable 110 up and down from the lower portion to the upper portion by the rotation of the wheels 112a-d. Electric motors 122a-d drive the wheels 112a-d via respective drive belts 124a-d for the sensing device 100. The sensing device is configured to gradually accelerate and decelerate in order to not spin the wheels 112a-d. The electric motors 122a-d are responsive to remote controls 306 operated by the inspector 300.

The sensing device 100 also includes hydraulic arms 126a, 126b that are used to maintain contact of the wheels 112a-d with the surface of the support cable 110. The hydraulic arms 126a, 126b force the wheels 112a-d of to make secure contact to the support cable 110.

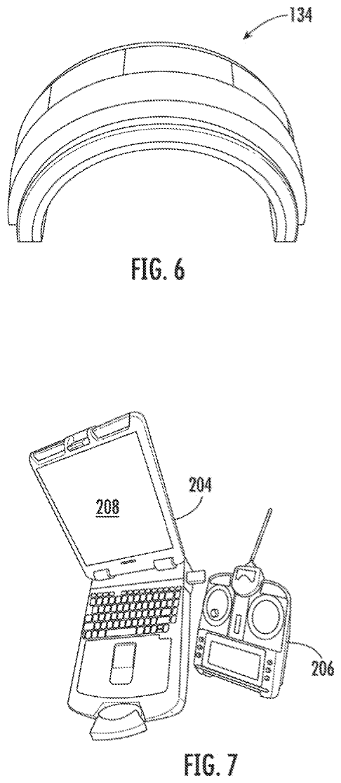

Referring now to FIG. 7, the control station 204 and joystick 206 are shown that are used in cooperation with the sensing device 100. In a particular embodiment, the joystick 206 is used to transmit wireless signals to the sensing device 100. For example, wireless signals may be transmitted to the electric motors 122a-d to drive the wheels 112a-d forward or in reverse, which corresponds to moving up or down the support cable 110. The control station 204 may include a video monitor 208 that is used for displaying data received from the sensing device 100.

Referring now to FIG. 8, results of a nondestructive evaluation of broadcast tower support cables 110 can be generated in a graph 300 to make it easy to interpret by the inspector. The results are included as part of a condition assessment report that is generated using the inspection results from the sensing device 100 and identifies locations and sizes of these discontinuities. By accurately detecting deficient areas within the support cables 110, repairs can be made more quickly and can be more efficiently conducted.

For example, the results of measurements from the sensing device 100 (e.g. raw voltage measurements) are plotted along a measurement line 301 and where magnetic flux leakage is detected is shown in portion 303 of the graph 300. A correlating chart 302 reflects loss of magnetic area (LMA) values 304. As can be seen in FIG. 8, portion 302 of the graph 300 indicates a relative loss of magnetic area and area within the broadcast tower support cable 110 that should be flagged for further inspection and/or repair.

The present inspection system is designed to overcome the shortcomings of the current techniques and methodologies in the art and assist in the preservation of service life of broadcast towers. In particular, the system is configured to pinpoint discontinuities within broadcast tower support cables 110, which may indicate need for a repair and helps to manage maintenance over time.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A robotic inspection system to detect discontinuities within broadcast tower support cables, the system comprising:
a self-propelled sensing device configured to move along a broadcast tower support cable to detect magnetic flux leakage; and
a control station configured to wirelessly interface with the sensing device, the control station configured to generate a broadcast tower support cable condition assessment report from the detection of the magnetic flux leakage to identify locations and sizes of the discontinuities within the broadcast tower support cable.

2. The robotic inspection system of claim 1, wherein the sensing device comprises a sensor array.

3. The robotic inspection system of claim 2, wherein the sensing device comprises a plurality of sets of rare-earth magnets grouped in measurement channels, wherein each of which delivers a cross-sectional magnetic field.

4. The robotic inspection system of claim 3, wherein the sensing device comprises a processor configured to analyze raw voltage measurements.

5. The robotic inspection system of claim 2, wherein the sensing device comprises an annulus shape.

6. The robotic inspection system of claim 2, wherein the sensor array comprises an inductive coil sensor configured to detect the magnetic flux leakage to indicate a discontinuity within the broadcast tower support cable.

7. The robotic inspection system of claim 2, wherein the sensor array comprises a Hall effect sensor configured to detect the magnetic flux leakage to indicate a discontinuity within the broadcast tower support cable.

8. The robotic inspection system of claim 3, wherein the magnets are configured to magnetize the broadcast tower support cable along a longitudinal direction.

9. The robotic inspection device of claim 2, wherein the sensor array is configured to detect the magnetic flux leakage perpendicular to a surface of the broadcast tower support cable.

10. The robotic inspection system of claim 2, wherein the sensing device comprises an annulus shape configured to open to be secured completely around a broadcast tower support cable.

11. A robotic inspection system to detect discontinuities within broadcast tower support cables, the system comprising:
a sensing device configured to move along a broadcast tower support cable to detect magnetic flux leakage;
a sensor array coupled to the sensing device; and
a plurality of magnets coupled to the sensing device to magnetize the broadcast tower support cable.

12. The robotic inspection system of claim 11, wherein the sensing device comprises a processor coupled to the sensor array and configured to analyze raw voltage measurements.

13. The robotic inspection system of claim 11, wherein the sensing device comprises an annulus shape.

14. The robotic inspection system of claim 11, wherein the sensor array comprises an inductive coil sensor configured to detect the magnetic flux leakage to indicate a discontinuity within the broadcast tower support cable.

15. The robotic inspection system of claim 11, wherein the sensor array comprises a Hall effect sensor configured to detect the magnetic flux leakage to indicate a discontinuity within the broadcast tower support cable.

16. The robotic inspection system of claim 11, wherein the magnets are configured to magnetize the broadcast tower support cable along a longitudinal direction.

17. The robotic inspection device of claim 11, wherein the sensor array is configured to detect the magnetic flux leakage perpendicular to a surface of the broadcast tower support cable.

18. The robotic inspection system of claim 11, wherein the sensing device comprises an annulus shape configured to open to be secured completely around the broadcast tower support cable.

19. A sensing device to detect discontinuities within broadcast tower support cables, the sensing device comprising:
a sensor array to detect magnetic flux leakage within a broadcast tower support cable; and
a plurality of magnets configured to magnetize the broadcast tower support cable;
wherein the sensing device having an annulus shape that fits around the broadcast tower support cable.

20. The sensing device of claim 19, wherein the sensor array comprises an inductive coil sensor or Hall effect sensor configured to detect the magnetic flux leakage to indicate a discontinuity within the broadcast tower support cable.
